(19) United States
(12) Patent Application Publication
(10) Pub. No.: US 2025/0171893 A1
(43) Pub. Date: May 29, 2025

(54) METHOD OF FORMING CARBON-BASED FILM AND FILM FORMING APPARATUS

(71) Applicant: Tokyo Electron Limited, Tokyo (JP)

(72) Inventors: Tadashi MITSUNARI, Nirasaki City (JP); Miyako KANEKO, Nirasaki City (JP); Naoko SUZUKI, Nirasaki City (JP); Takahiro SHINDO, Tokyo (JP)

(21) Appl. No.: 18/958,279

(22) Filed: Nov. 25, 2024

(30) Foreign Application Priority Data
Nov. 28, 2023 (JP) 2023-200333

(51) Int. Cl. C23C 16/26; C23C 16/04; C23C 16/505

(52) U.S. Cl. CPC C23C 16/26; C23C 16/042; C23C 16/505

(57) ABSTRACT

A method of forming a carbon-based film includes forming the carbon-based film on a substrate having a pattern, wherein, in the forming the carbon-based film, plasma is generated from a film-forming gas consisting of a hydrocarbon gas, argon gas, and hydrogen gas to selectively form the carbon-based film on a top of the pattern.

### CROSS-REFERENCE TO RELATED APPLICATION

This application is based upon and claims the benefit of priority from Japanese Patent Application No. 2023-200333, filed on Nov. 28, 2023, the entire content of which is incorporated herein by reference.

### TECHNICAL FIELD

The present disclosure relates to a method of forming a carbon-based film and a film forming apparatus.

### BACKGROUND

In semiconductor devices, techniques are known for selectively forming a carbon-based film on the top of a trench or hole formed on a mask or etching target film, in order to realize more complex-shaped wiring or finer wiring. For example, in the technique described in Patent Document 1, a carbon-based film is formed on the top of a trench formed on a silicon base material. Specifically, a flowable film, which is an amorphous carbon polymer film, is primarily deposited on the bottom of the trench in the base material, and then, the flowable film on the bottom is exposed to a nitrogen plasma, so that the flowable film on the bottom is etched while forming a gaseous CₓN_{y}H_{z} species from the flowable film. At this time, since the adhesion coefficient of the CₓN_{y}H_{z} species to the exposed silicon on the top of the trench is higher than that of the flowable film on the bottom, the CₓN_{y}H_{z} species is selectively redeposited on the top of the trench. This results in the selective formation of a carbon-based film on the top of the trench.

### PRIOR ART DOCUMENT

### Patent Document

Patent Document 1: Japanese Laid-Open Publication No. 2021-019199

### SUMMARY

According to one embodiment of the present disclosure, a method of forming a carbon-based film includes forming the carbon-based film on a substrate having a pattern, wherein, in the forming the carbon-based film, plasma is generated from a film-forming gas consisting of a hydrocarbon gas, argon gas, and hydrogen gas to selectively form the carbon-based film on a top of the pattern.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a cross-sectional view schematically illustrating a configuration of a film forming apparatus as one embodiment of the technique according to the present disclosure.

FIGS. 2A to 2C are diagrams illustrating a film-forming pattern when a temperature of a wafer is varied during film formation in an evaluation apparatus.

FIGS. 3A and 3B are diagrams illustrating a film-forming pattern when an addition rate of a hydrogen gas in a film-forming gas is varied during film formation in the evaluation apparatus.

FIGS. 4A and 4B are diagrams illustrating a film-forming pattern when the addition rate of the hydrogen gas in the film-forming gas is varied during film formation in the evaluation apparatus.

FIGS. 5A and 5B are diagrams illustrating effects of the temperature of the wafer and the addition rate of the hydrogen gas in the film-forming gas on a film-forming pattern of a carbon-based film.

FIGS. 6A and 6B are diagrams illustrating a film-forming pattern in the wafer undergoing film formation when an aspect ratio of a trench in an oxide layer is varied.

FIGS. 7A and 7B are diagrams illustrating effects of the aspect ratio of the trench on a film-forming pattern of a carbon-based film.

FIGS. 8A to 8C are diagrams illustrating a film-forming pattern in a wafer undergoing film formation when ion energy of plasma is varied.

FIGS. 9A and 9B are diagrams schematically illustrating calculation results of a variation in the angular distribution of ion energy when maximum ion energy of plasma used for film formation differs.

FIGS. 10A to 10C are diagrams illustrating a film-forming pattern in a wafer undergoing film formation when a configuration of the film forming apparatus is changed.

FIGS. 11A to 11F are process diagrams illustrating an example where a carbon-based film is selectively formed on a top of a metal protrusion, which serves as a wiring layer protruding from an interlayer insulating film.

FIGS. 12A to 12E are process diagrams illustrating an example where a carbon-based film is selectively formed on a top of a trench in a hard mask.

FIGS. 13A to 13D are process diagrams illustrating another example where a carbon-based film is selectively formed on the top of the trench in the hard mask.

FIG. 14 is a drawing illustrating a first modification of a film forming apparatus that executes a method of forming a carbon-based film according to the present embodiment.

FIG. 15 is a drawing illustrating a second modification of a film forming apparatus that executes the method of forming a carbon-based film according to the present embodiment.

FIGS. 16A to 16C are diagrams illustrating another modification of a film forming apparatus that executes the method of forming a carbon-based film according to the present embodiment.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

By the way, in the technique described in Patent Document 1, after depositing the flowable film on the bottom of the trench, the carbon-based film is redeposited on the top of the trench by exposure to the nitrogen plasma. Therefore, forming the carbon-based film on the top of the trench requires two steps, which reduces throughput.

Further, in the technique described in Patent Document 1, as the redeposition of the carbon-based film on the top of the trench progresses, there is a risk of overhang of the carbon-based film occurring, which will block the trench.

In contrast, the technique according to the present disclosure improves throughput while preventing the occurrence of overhang of a carbon-based film when selectively forming the carbon-based film on the top of a pattern such as a trench or hole.

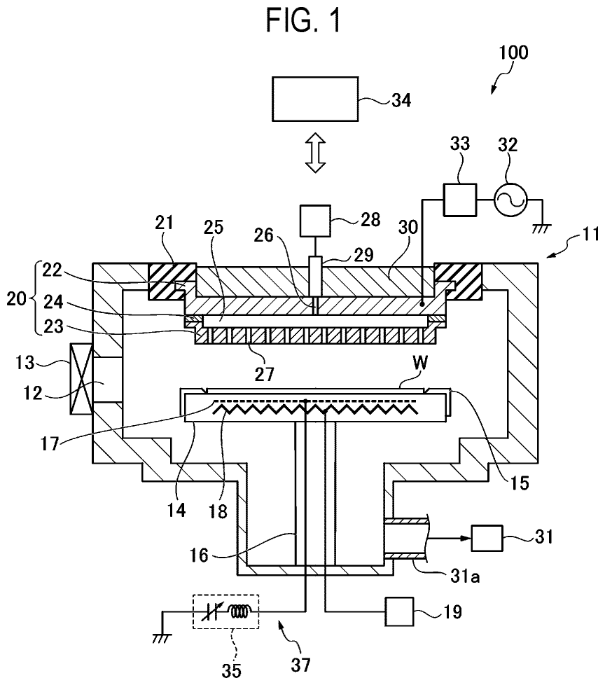

Hereinafter, one embodiment of the technique according to the present disclosure will be described with reference to the drawings. FIG. 1 is a cross-sectional view schematically illustrating a configuration of a film forming apparatus according to the present embodiment. This film forming apparatus is a Plasma-Enhanced Chemical Vapor Deposition (PECVD) apparatus that performs film formation by generating plasma from a film-forming gas.

In FIG. 1, the film forming apparatus 100 includes a generally cylindrical chamber 11 (processing chamber) that accommodates a wafer W (substrate), and plasma is generated from a film-forming gas in the interior of the chamber 11, as described later. The chamber 11 is provided at a sidewall thereof with a loading port 12 for loading or unloading the wafer W to or from the interior of the chamber 11, and the loading port 12 is opened or closed by a gate valve 13.

A generally disc-shaped stage 14 is arranged in the interior of the chamber 11, and the wafer W is placed on the stage 14. Further, an annular guide ring 15 is arranged on the outer edge of the stage 14 to surround the placed wafer W. The stage 14 is supported by a cylindrical support member 16 that extends upward from the bottom of the chamber 11.

Further, a lower electrode 17, a heater 18, and a coolant passage (not illustrated) are embedded inside the stage 14. The heater 18 generates heat upon receiving power supplied from a heater power supply 19 to heat the placed wafer W, and the coolant passage circulates a coolant supplied from the outside, thereby cooling the placed wafer W. In addition, to improve heat transfer between the stage 14 and the wafer W, a heat transfer gas is supplied between the stage 14 and the wafer W.

In addition, an upper electrode 20 is arranged on the ceiling of the chamber 11 so as to face the stage 14, and an insulating member 21 is arranged between the chamber 11 and the upper electrode 20. The upper electrode 20 includes a base member 22, a ceiling plate 23, and an intermediate member 24. The base member 22, ceiling plate 23, and intermediate member 24 are made of a conductive member, for example, aluminum. The ceiling plate 23, intermediate member 24, and base member 22 are arranged in this order from below, but the ceiling plate 23 and base member 22 are spaced apart from each other by the generally annular intermediate member 24 to form a gas diffusion space 25 therebetween. The base member 22 is formed by making a gas introduction port 26 that is in communication with the gas diffusion space 25 from above, while the ceiling plate 23 is formed by making a plurality of gas holes 27 that allow for communication between the gas diffusion space 25 and the interior of the chamber 11.

Further, the film forming apparatus 100 includes a gas supplier 28, and the gas supplier 28 is connected to the gas introduction port 26 through a gas pipe 29. The gas supplier 28 includes a gas source, a flow controller, and an on-off valve, and supplies a process gas, such as a film-forming gas, that will form plasma. The supplied film-forming gas is introduced into the gas diffusion space 25 through the gas introduction port 26, and is also diffused and introduced to the interior of the chamber 11 from the respective gas holes 27. Thus, the upper electrode 20 functions as a shower head. An insulating member 30 is arranged above the upper electrode 20. In addition, in the present embodiment, the film-forming gas supplied by the gas supplier 28 is consisting of an acetylene gas (hydrocarbon gas), argon gas, and hydrogen gas.

The film forming apparatus 100 further includes an exhaust device 31, and the exhaust device 31 is formed of, for example, a turbo molecular pump or a dry pump. The exhaust device 31 depressurizes the interior of the chamber 11 through an exhaust pipe 31a connected to the bottom of the chamber 11.

The film forming apparatus 100 further includes a radio frequency power supply 32, and the radio frequency power supply 32 is connected to the upper electrode 20 via a matcher 33. The matcher 33 matches the load impedance of the radio frequency power supply 32 to the output impedance of the radio frequency power supply 32. The radio frequency power supply 32 supplies radio frequency power within a frequency range from 40 MHz to 460 MHz to the upper electrode 20.

Therefore, in the film forming apparatus 100, radio frequency power with a frequency of 40 MHz or higher is supplied to the upper electrode 20. Generally, when radio frequency power with a frequency of 40 MHz or higher is supplied to the upper electrode 20 to generate plasma, the generated plasma is a high-density plasma and the electrical impedance of the plasma is reduced. Thus, the maximum value of a radio frequency voltage applied to the upper electrode 20 is lower compared to when a low-frequency voltage (frequency: 200 kHz to 13 MHz) is supplied. In other words, when radio frequency power is supplied to the upper electrode 20, the plasma potential is reduced, which in turn reduces the sheath voltage that contributes to the acceleration of ions in the plasma. Additionally, as the applied voltage increases in frequency, the sheath also vibrates at a higher speed, so the ion's ability to follow the sheath voltage deteriorates. As a result, the ion energy imparted from the plasma to the wafer W placed on the stage 14 is reduced.

The film forming apparatus 100 further includes a controller 34, and the controller 34 controls each component of the film forming apparatus 100. The controller 34 is a computer equipped with a processor, a memory, an input device, a display device, a signal input/output interface, and others. The memory of the controller 34, which is a non-transitory computer readable medium, stores control programs and recipe data. When executing film formation in the film forming apparatus 100, the processor of the controller 34 executes a corresponding control program and controls each component of the film forming apparatus 100 based on the recipe data.

Specifically, the controller 34 controls the gas supplier 28 and the exhaust device 31 to adjust the internal pressure of the chamber 11 and controls the radio frequency power supply 32 to supply radio frequency power to the upper electrode 20. Further, the controller 34 controls the gas supplier 28 to diffuse and introduce the film-forming gas to the interior of the chamber 11. At this time, the electric field generated by the radio frequency power supplied to the upper electrode 20 excites individual gas molecules of the film-forming gas to generate plasma. This plasma performs film formation on the wafer W.

The film forming apparatus 100 further includes a first impedance circuit 35. The first impedance circuit 35 is positioned in a first electrical path 37 that connects the lower electrode 17 to the ground. The first impedance circuit 35 includes at least one of an inductor or a condenser, and by connecting them in series or parallel, it may change the impedance between the lower electrode 17 and the ground. Further, the inductor or condenser included in the first impedance circuit 35 may be either a fixed element or a variable element.

Such a change in impedance enables control to weaken the electrical coupling between the upper electrode 20 and the lower electrode 17, thereby further reducing a radio frequency current flowing to the lower electrode 17. As a result, the energy value of ions entering the wafer W may be controlled more precisely.

By the way, the applicant of the present disclosure conducted film formation on a wafer W using an evaluation apparatus 40, which has a structure similar to that of the film forming apparatus 100 of FIG. 1, while changing the temperature of the wafer W or the addition rate of the hydrogen gas in the film-forming gas, and confirmed a film forming pattern of a carbon-based film in the wafer W. In addition, the temperature of the wafer W in the present embodiment actually refers to the temperature of the stage 14 on which the wafer W is placed.

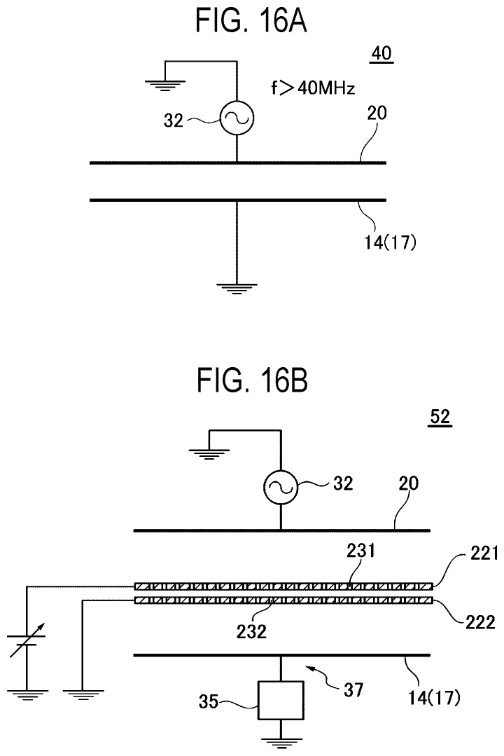

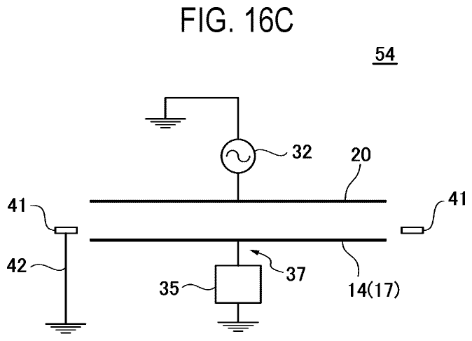

A configuration of the evaluation apparatus 40 is illustrated in a simplified manner in FIG. 16A, and other components (not illustrated) thereof are the same as those in the film forming apparatus 100. In the evaluation apparatus 40, radio frequency power with an extremely high frequency, for example, radio frequency power with a frequency higher than 40 MHz, is supplied to the upper electrode 20 from the radio frequency power supply 32. Plasma generated at this time is a high-density plasma, and the electrical impedance of the plasma is reduced. Thus, a voltage amplitude Vpp at the upper electrode 20 is reduced, so that the plasma potential between the upper electrode 20 and the lower electrode 17 is reduced and the sheath voltage is reduced. Additionally, since the sheath vibrates at a high speed, the ion's ability to follow the sheath voltage deteriorates. As a result, similar to the film forming apparatus 100, the ion energy imparted to the wafer W placed on the stage 14 is reduced. In other words, the evaluation apparatus 40 may reproduce the film formation in the film forming apparatus 100.

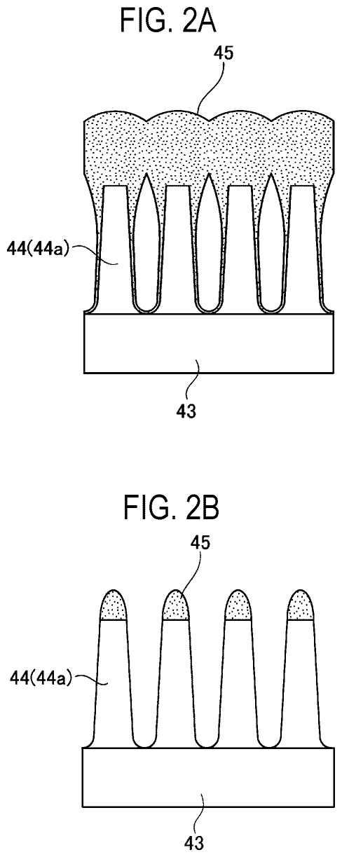

FIGS. 2A to 2C are diagrams illustrating a film-forming pattern when a temperature of the wafer W is varied during film formation in the evaluation apparatus 40. FIGS. 2A to 2C illustrate enlarged partial cross-sectional views of an oxide layer 44, which is formed on a surface of the wafer W using silicon as a base material 43 and which has a plurality of patterned trenches. In addition, the oxide layer 44 serves as an underlying layer for a carbon-based film 45 which is to be formed.

At this time, the applicant set an addition rate of the acetylene gas in the film-forming gas to 3% (with a flow rate of 30 sccm), an addition rate of the argon gas to 94% (with a flow rate of 1,000 sccm), and an addition rate of the hydrogen gas to 3% (with a flow rate of 30 sccm). Further, the addition rate of each gas in the present embodiment is the flow rate ratio of each gas relative to the total gas flow rate of the film-forming gas. Further, the film formation was performed on the wafer W by generating plasma from the film-forming gas under a condition where the internal pressure of the chamber 11 was set to 1 Torr, and radio frequency power with a frequency of 40 MHz was supplied at 500 W to the upper electrode 20 from the radio frequency power supply 32. Further, the temperature of the wafer W was set to 200 degrees C. and 400 degrees C.

FIG. 2A illustrates a film-forming pattern of the carbon-based film 45 when the wafer W was set to a temperature of 200 degrees C. during film formation, while FIG. 2B illustrates a film-forming pattern of the carbon-based film 45 when the wafer W was set to a temperature of 400 degrees C. during film formation.

First, when the wafer W was set to a temperature of 200 degrees C., it was confirmed that the carbon-based film 45 was formed with overhang to block a trench on the top of a fin 44a (corresponding to the top of the trench) sandwiched between respective trenches of the oxide layer 44. Further, it was confirmed that the carbon-based film 45 was formed inside the trench as well. In other words, it was confirmed that the carbon-based film 45, which is not appropriate for selective formation on the top of the fin 44a, was formed. On the other hand, when the wafer W was set to a temperature of 400 degrees C., it was confirmed that the carbon-based film 45 was formed only on the top of the fin 44a, that the carbon-based film 45 did not overhang toward the trench, and that the carbon-based film 45 was hardly formed inside the trench. In other words, it was confirmed that the carbon-based film 45, which is appropriate for selective formation on the top of the fin 44a, was formed.

Further, the applicant changed the addition rate of the hydrogen gas in the film-forming gas to 10% (with a flow rate of 100 sccm) without changing the flow rate of the acetylene gas or argon gas, and then set the temperature of the wafer W to 300 degrees C. Further, plasma was generated from the film-forming gas to perform film formation on the wafer W. FIG. 2C illustrates a film-forming pattern of the carbon-based film 45 at this time.

When the wafer W was set to a temperature of 300 degrees C., it was also confirmed that the carbon-based film 45 was formed only on the top of the fin 44a, that the carbon-based film 45 did not overhang toward the trench, and that the carbon-based film 45 was hardly formed inside the trench. In other words, it was confirmed that, as with the temperature of the wafer W set to 400 degrees C., the carbon-based film 45, which is appropriate for selective formation on the top of the fin 44a, was formed.

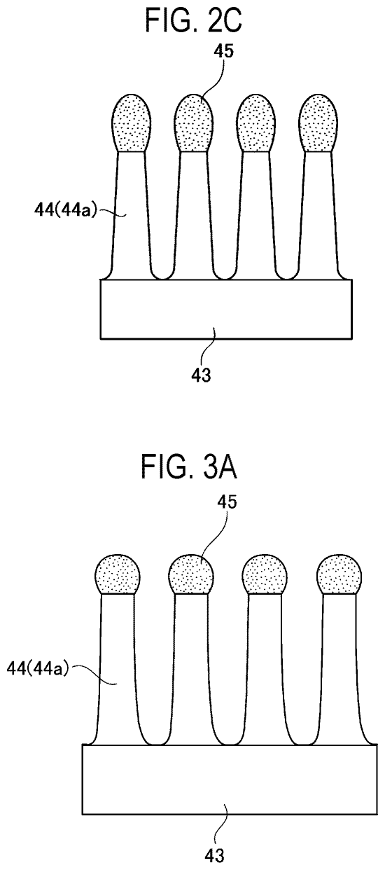

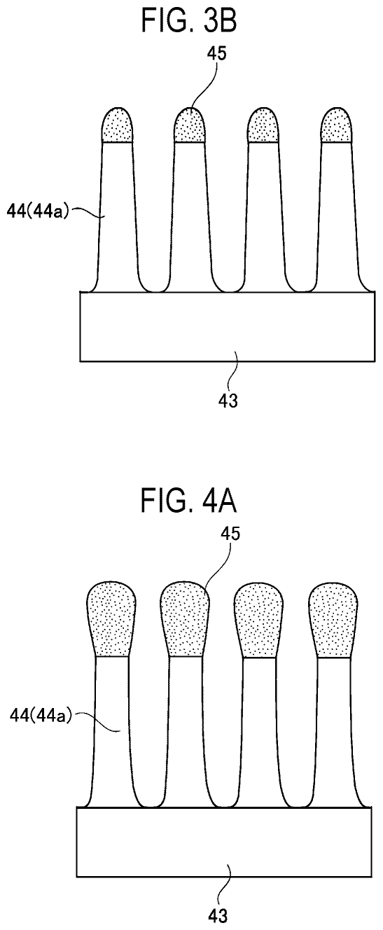

FIGS. 3A and 3B are diagrams illustrating a film-forming pattern when the addition rate of the hydrogen gas in the film-forming gas is varied during film formation in the evaluation apparatus 40. Similar to FIGS. 2A to 2C, FIGS. 3A and 3B illustrate enlarged partial cross-sectional views of the oxide layer 44 on the surface of the wafer W where a plurality of trenches have been formed.

At this time, the applicant set the internal pressure of the chamber 11 to 1 Torr and the temperature of the wafer W to 400 degrees C. Further, radio frequency power with a frequency of 40 MHz was supplied at 500 W to the upper electrode 20 from the radio frequency power supply 32, and plasma was generated from the film-forming gas to perform film formation on the wafer W. Further, the flow rate of the acetylene gas in the film-forming gas was set to 30 sccm, the flow rate of the argon gas was set to 1,000 sccm, and the addition rate of the hydrogen gas in the film-forming gas was set to 1.7% and 3%.

FIG. 3A illustrates a film-forming pattern of the carbon-based film 45 when the addition rate of the hydrogen gas was set to 1.7% during film formation, while FIG. 3B illustrates a film-forming pattern of the carbon-based film 45 when the addition rate of the hydrogen gas was set to 3% during film formation.

First, when the addition rate of the hydrogen gas was set to 1.7%, it was confirmed that the carbon-based film 45 was formed only on the top of the fin 44a, but the carbon-based film 45 swelled laterally and overhung toward the trench. In other words, it was confirmed that the carbon-based film 45, which is not appropriate for selective formation on the top of the fin 44a, was formed. On the other hand, when the addition rate of the hydrogen gas was set to 3%, it was confirmed that the carbon-based film 45 was formed only on the top of the fin 44a, that the carbon-based film 45 did not overhang toward the trench, and that the carbon-based film 45 was hardly formed inside the trench. In other words, it was confirmed that the carbon-based film 45, which is appropriate for selective formation on the top of the fin 44a, was formed.

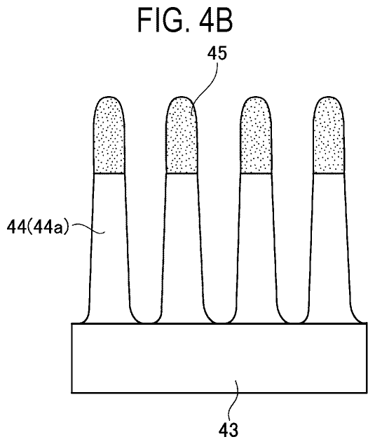

Similar to FIGS. 3A and 3B, FIGS. 4A and 4B are diagrams illustrating a film-forming pattern when the addition rate of the hydrogen gas in the film-forming gas is varied during film formation in the evaluation apparatus 40.

At this time, the applicant set the internal pressure of the chamber 11 to 1 Torr and the temperature of the wafer W to 350 degrees C. Further, radio frequency power with a frequency of 40 MHz was supplied at 500 W to the upper electrode 20 from the radio frequency power supply 32, and plasma was generated from the film-forming gas to perform film formation on the wafer W. Further, the flow rate of the acetylene gas in the film-forming gas was set to 30 sccm, the flow rate of the argon gas was set to 1,000 sccm, and the addition rate of the hydrogen gas in the film-forming gas was set to 2% (with a flow rate of 20 sccm) and 4% (with a flow rate of 40 sccm).

FIG. 4A illustrates a film-forming pattern of the carbon-based film 45 when the addition rate of the hydrogen gas was set to 2% during film formation, while FIG. 4B illustrates a film-forming pattern of the carbon-based film 45 when the addition rate of the hydrogen gas was set to 4% during film formation.

First, when the addition rate of the hydrogen gas was set to 2%, it was confirmed that, similar to when the addition rate of the hydrogen gas was set to 1.7%, the carbon-based film 45 was formed only on the top of the fin 44a, but the carbon-based film 45 swelled laterally and overhung toward the trench. In other words, it was confirmed that the carbon-based film 45, which is not appropriate for selective formation on the top of the fin 44a, was formed. On the other hand, when the addition rate of the hydrogen gas was set to 4%, it was confirmed that the carbon-based film 45 was formed only on the top of the fin 44a, that the carbon-based film 45 did not overhang toward the trench, and that the carbon-based film 45 was hardly formed inside the trench. In other words, it was confirmed that the carbon-based film 45, which is appropriate for selective formation on the top of the fin 44a, was formed.

From the confirmation results illustrated in FIGS. 2A to 4B, it was found that as the temperature of the wafer W is increased and the addition rate of the hydrogen gas is increased, the overhang of the carbon-based film 45 formed on the top of the fin 44a is reduced and it becomes difficult for the carbon-based film 45 to be formed inside the trench. As for a reason why such a phenomenon occurs, the applicant assumed the mechanism described below.

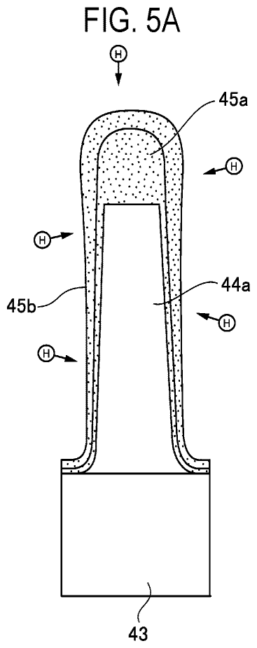

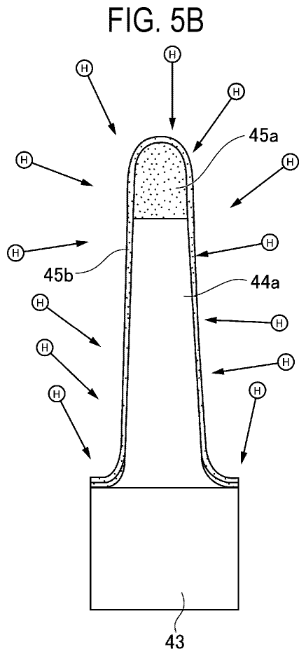

FIGS. 5A and 5B are diagrams illustrating effects of the temperature of the wafer W and the addition rate of the hydrogen gas in the film-forming gas on a film-forming pattern of the carbon-based film 45.

First, a film-forming pattern when the temperature of the wafer W is low and the addition rate of the hydrogen gas is low, as illustrated in FIG. 5A, will be described.

By the way, plasma generated from the acetylene gas, which is a main source of the film formation of the carbon-based film 45, contains hydrocarbon ions and hydrocarbon radicals, but hydrocarbon ions are highly anisotropic and tend to adhere approximately perpendicularly to the fin 44a of the oxide layer 44. On the other hand, hydrocarbon radicals are highly isotropic and adhere to the fin 44a of the oxide layer 44 from all directions.

Further, when the temperature of the wafer W is low, the ambient temperature near the wafer W also decreases, but the adhesion probability of hydrocarbon radicals and hydrocarbon ions remains high at a low ambient temperature. Accordingly, hydrocarbon ions are mainly deposited vertically on the top of the fin 44a, and hydrocarbon radicals are deposited not only on the top of the fin 44a but also on the side of the fin 44a or the bottom of the trench. In addition, for ease of understanding, in FIG. 5A, a carbon-based film derived from hydrocarbon ions is indicated by reference numeral 45a, and a carbon-based film derived from hydrocarbon radicals is indicated by reference numeral 45b. However, actually, the carbon-based film derived from hydrocarbon ions and the carbon-based film derived from hydrocarbon radicals are mixed with each other to form the carbon-based film 45.

By the way, the carbon-based film 45 is isotropically etched by hydrogen radicals contained in a hydrogen plasma generated from the hydrogen gas, but when the ambient temperature is low, the etching power of the hydrogen radicals is weak, so that the carbon-based film 45 is hardly etched. In addition, in the drawings, the magnitude of the etching power is schematically indicated by the lengths of the arrows.

As a result, when the temperature of the wafer W is low, the carbon-based film 45 grows on the side and top of the fin 44a or the bottom of the trench. In particular, on the top of the fin 44a, not only does the carbon-based film 45b derived from hydrocarbon radicals grow, but also the carbon-based film 45a derived from hydrocarbon ions grows significantly. This leads to a remarkable growth of the carbon-based film 45, and overhang of the carbon-based film 45 toward the trench.

Next, a film-forming pattern when the temperature of the wafer W is high and the addition rate of the hydrogen gas is high, as illustrated in FIG. 5B, will be described.

When the temperature of the wafer W is high, the ambient temperature near the wafer W also increases. While the adhesion probability of hydrocarbon ions remains high when the ambient temperature is high, the adhesion probability of hydrocarbon radicals decreases. Accordingly, hydrocarbon ions are vertically deposited on the top of the fin 44a, but the degree of deposition of hydrocarbon radicals on the side of the fin 44a or the bottom of the trench is reduced. In other words, the carbon-based film 45a derived from hydrocarbon ions formed on the top of the fin 44a has a similar thickness to that when the temperature of the wafer W is low. However, the carbon-based film 45b derived from hydrocarbon radicals formed on the side of the fin 44a or the bottom of the trench becomes much thinner compared to when the temperature of the wafer W is low (FIG. 5B).

Further, when the ambient temperature is high, the etching power of hydrogen radicals increases, resulting in the isotropic etching of the carbon-based film 45. In this way, the thin carbon-based film 45b derived from hydrocarbon radicals inside the trench is removed by etching, making it difficult for the carbon-based film 45 to be formed inside the trench. Furthermore, the thin carbon-based film 45b derived from hydrocarbon radicals even on the top of the fin 44a is removed by etching, leaving only the thick carbon-based film 45a derived from hydrocarbon ions. As a result, the growth of the carbon-based film 45 is prevented to some extent, so that the carbon-based film 45 does not overhang toward the trench.

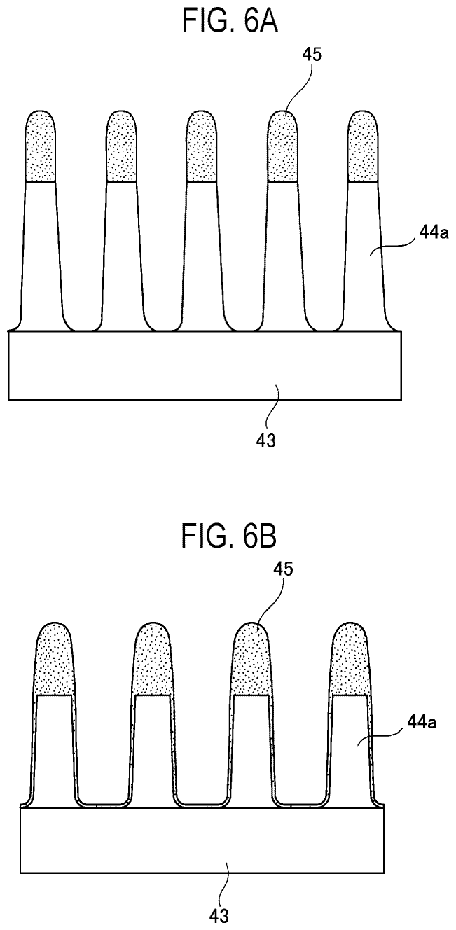

Further, the applicant conducted film formation on the wafer W using the evaluation apparatus 40 while changing the aspect ratio (height-to-width ratio) of the trench in the oxide layer 44, and confirmed a film-forming pattern of a carbon-based film on the wafer W. FIGS. 6A and 6B are diagrams illustrating a film-forming pattern in the wafer W undergoing film formation when the aspect ratio of the trench in the oxide layer 44 is varied. Similar to FIGS. 2A to 2C, FIGS. 6A and 6B illustrate enlarged partial cross-sectional views of the oxide layer 44.

At this time, the applicant set the internal pressure of the chamber 11 to 1 Torr and the temperature of the wafer W to 370 degrees C. Further, radio frequency power with a frequency of 40 MHz was supplied at 500 W to the upper electrode 20 from the radio frequency power supply 32, and plasma was generated from the film-forming gas to perform film formation on the wafer W. Further, the applicant set the addition rate of the acetylene gas in the film-forming gas to 3% (with a flow rate of 30 sccm), the addition rate of the argon gas to 94% (with a flow rate of 1,000 sccm), and the addition rate of the hydrogen gas to 3% (with a flow rate of 30 sccm).

FIG. 6A illustrates a film-forming pattern of the carbon-based film 45 when film formation was performed on the wafer W in which the aspect ratio of the trench in the oxide layer 44 was set to 4. FIG. 6B illustrates a film-forming pattern of the carbon-based film 45 when film formation was performed on the wafer W in which the aspect ratio of the trench in the oxide layer 44 was set to 2.

First, in the wafer W in which the aspect ratio of the trench was set to 4, it was confirmed that the carbon-based film 45 was formed only on the top of the fin 44a, that the carbon-based film 45 did not overhang toward the trench, and that the carbon-based film 45 was hardly formed inside the trench. In other words, it was confirmed that the carbon-based film 45, which is appropriate for selective formation on the top of the fin 44a, was formed. Further, in the wafer W in which the aspect ratio of the trench was set to 2, the carbon-based film 45 was formed not only on the top of the fin 44a but also inside the trench, but the carbon-based film 45 inside the trench was very thin to the extent that it may be easily removed later with light ashing. Further, the carbon-based film 45 on the top of the fin 44a did not overhang toward the trench. In other words, it was confirmed that the carbon-based film 45, which is generally appropriate for selective formation on the top of the fin 44a, was formed.

From the confirmation results illustrated in FIGS. 6A and 6B, it was found that when the aspect ratio of the trench in the oxide layer 44 is 2 or higher, a generally appropriate carbon-based film 45 was formed as the carbon-based film to be selectively formed on the top of the fin 44a. On the other hand, it was also found that when the aspect ratio of the trench is high, it becomes difficult for the carbon-based film 45 to be formed inside the trench. As for a reason why such a phenomenon occurs, the applicant assumed the mechanism described below.

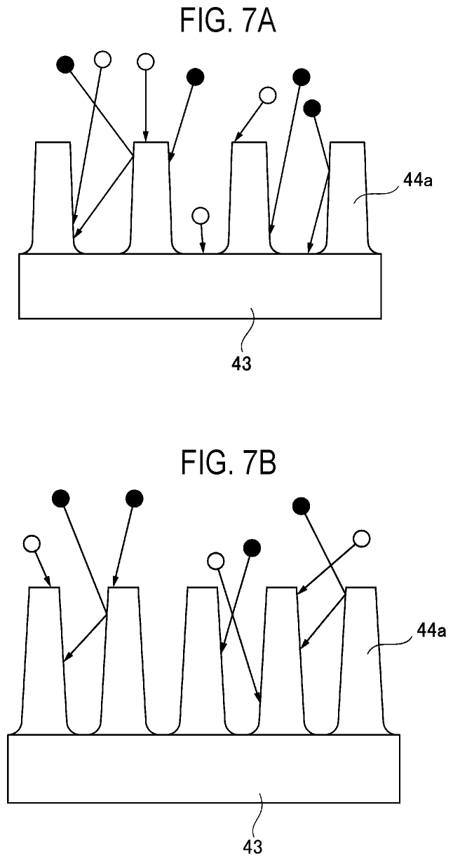

FIGS. 7A and 7B are diagrams illustrating effects of the aspect ratio of the trench on a film-forming pattern of the carbon-based film 45. In FIGS. 7A and 7B, hydrocarbon ions are indicated by “o”, and hydrocarbon radicals are indicated by “●”.

As described above, the carbon-based film 45 inside the trench is mainly formed by the adhesion of highly isotropic hydrocarbon radicals. Further, some of hydrocarbon radicals enter the trench at an angle. Here, as illustrated in FIG. 7A, when the aspect ratio of the trench decreases, a trench opening becomes wider, allowing hydrocarbon radicals that attempt to enter the trench at an angle to easily enter and adhere to a sidewall of the fin 44a or the bottom of the trench. Accordingly, when the aspect ratio is low, the carbon-based film 45 tends to be formed more easily inside the trench.

On the other hand, as illustrated in FIG. 7B, when the aspect ratio of the trench increases, the trench opening becomes narrower, obstructing hydrocarbon radicals that attempt to enter the trench at an angle by the top of the fin 44a (shielding effect). Further, even if hydrocarbon radicals enter the trench and adhere to the sidewall of the fin 44a, an increased surface area of the sidewall of the fin 44a lowers the adhesion density of hydrocarbon radicals, making it difficult for the carbon-based film 45 to be formed thickly on the sidewall of the fin 44a. Furthermore, since the adhesion probability of hydrocarbon radicals to the sidewall of the fin 44a until hydrocarbon radicals reach the bottom of the trench increases, it becomes more difficult for hydrocarbon radicals to reach the bottom of the trench, making it less likely that the carbon-based film 45 will be formed thickly on the bottom of the trench. Accordingly, when the aspect ratio increases, the tendency for the carbon-based film 45 to be formed inside the trench decreases.

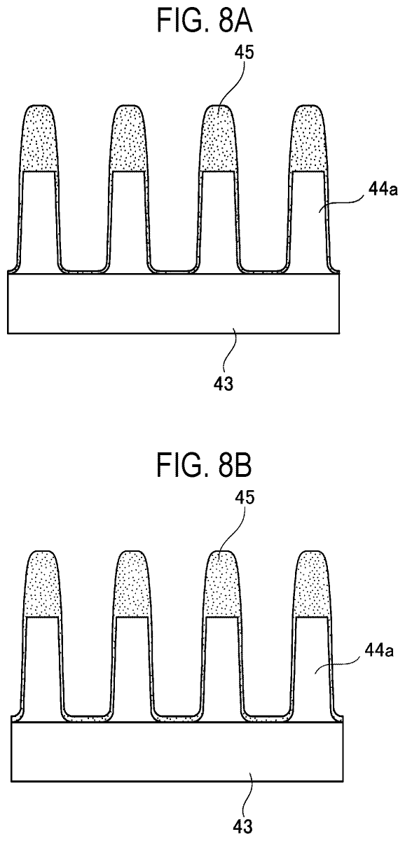

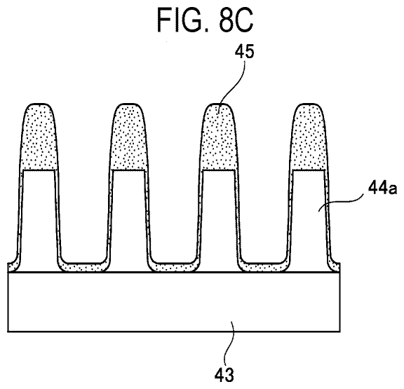

Further, the applicant confirmed a film-forming pattern of the carbon-based film in the wafer W by using the evaluation apparatus 40 and varying ion energy of plasma generated during film formation on the wafer W in which the trench in the oxide layer 44 has an aspect ratio of 4. FIGS. 8A to 8C are diagrams illustrating a film-forming pattern in the wafer undergoing film formation when ion energy of plasma is varied. Similar to FIGS. 2A to 2C, FIGS. 8A to 8C also illustrate enlarged partial cross-sectional views of the oxide layer 44.

At this time, the applicant set the internal pressure of the chamber 11 to 1 Torr and the temperature of the wafer W to 370 degrees C. Further, in order to vary ion energy of plasma, radio frequency power with a frequency of 40 MHz was supplied to the upper electrode 20 from the radio frequency power supply 32 at 500 W, 1 kW, or 2 kW, and plasma was generated from the film-forming gas to perform film formation on the wafer W. Further, the applicant set the addition rate of the acetylene gas in the film-forming gas to 3% (with a flow rate of 30 sccm), the addition rate of the argon gas to 94% (with a flow rate of 1,000 sccm), and the addition rate of the hydrogen gas to 3% (with a flow rate of 30 sccm).

Further, the applicant evaluated the maximum ion energy using an ion energy meter when the radio frequency power was varied to 500 W, 1 kW, and 1.5 kW, respectively, during film formation described above. Further, it was confirmed that the maximum ion energy at each radio frequency power level was 100 eV, 200 eV, and 300 eV, respectively.

FIG. 8A illustrates a film-forming pattern of the carbon-based film 45 under a condition where radio frequency power with a frequency of 40 MHz was supplied at 500 W, with the maximum ion energy of 100 eV. FIG. 8B illustrates a film-forming pattern when radio frequency power with a frequency of 40 MHz was supplied at 1 kW, with the maximum ion energy of 200 eV. FIG. 8C illustrates a film-forming pattern when radio frequency power with a frequency of 40 MHz was supplied at 1.5 kW, with the maximum ion energy of 300 eV.

First, as illustrated in FIG. 8A, under a condition where the maximum ion energy is 100 eV, it was confirmed that the carbon-based film 45 was formed only on the top of the fin 44a, that the carbon-based film 45 did not overhang toward the trench, and that the carbon-based film 45 was hardly formed inside the trench. In other words, it was confirmed that the carbon-based film 45, which is appropriate for selective formation on the top of the fin 44a, was formed.

Further, as illustrated in FIG. 8B, under a condition where the maximum ion energy is 200 eV, the carbon-based film 45 was formed not only on the top of the fin 44a but also on the bottom of the trench, but the carbon-based film 45 on the bottom of the trench was very thin to the extent that it may be easily removed later with light ashing. Further, the carbon-based film 45 on the top of the fin 44a did not overhang toward the trench. Therefore, it was confirmed that the carbon-based film 45, which is generally appropriate for selective formation on the top of the fin 44a, was formed.

On the other hand, as illustrated in FIG. 8C, under a condition where the maximum ion energy is 300 eV, a significant amount of carbon-based film 45 was formed on the top of the fin 44a. Although the carbon-based film 45 on the top of the fin 44a did not overhang toward the trench, it was also formed on the bottom of the trench. Further, the carbon-based film 45 on the bottom of the trench had a certain thickness, which could not be removed later by light ashing.

In other words, from the confirmation results illustrated in FIGS. 8A to 8C, it was found that when the maximum ion energy of the plasma used for film formation is 200 eV or lower, the carbon-based film 45 is hardly formed on the bottom of the trench, allowing for the selective formation of the carbon-based film 45 on the top of the fin 44a. On the other hand, it was found that when the maximum ion energy of the plasma used for film formation is 300 eV or higher, the carbon-based film 45 with a certain thickness is formed on the bottom of the trench, making it difficult to selectively form the carbon-based film 45 on the top of the fin 44a.

The applicant qualitatively investigated a reason why reducing the maximum ion energy of the plasma can prevent the formation of the carbon-based film on the bottom of the trench through plasma state calculations. FIGS. 9A and 9B are diagrams schematically illustrating the calculation results of an angular distribution of ion energy when the maximum ion energy of the plasma used for film formation differs. FIG. 9A illustrates a case where the maximum ion energy is 100 eV, and FIG. 9B illustrates a case where the maximum ion energy is 300 eV. Further, the arrows in FIGS. 9A and 9B indicate the magnitude of the ion proportion at the respective angles.

The applicant conducted calculations (simulations) of the plasma state under a film-forming condition that realizes a predetermined shape of the carbon-based film 45. From the calculation results at this time, it was found that as the maximum ion energy of the plasma increases, the angular distribution of ion energy varies due to an increase in ion energy. Specifically, it was found that when the maximum ion energy was low, for example, 100 eV, the angular distribution of ion energy becomes broader compared to when the maximum ion energy was high, for example, 300 eV. Furthermore, when the maximum ion energy was 100 eV, there was little difference in the proportion of ions at the respective angles (FIG. 9A). On the other hand, when the maximum ion energy was 300 eV, the angular distribution of ion energy became narrower, leading to differences in the proportion of ions at the respective angles, and in particular, the proportion of ions entering perpendicularly to the wafer W increased (FIG. 9B).

As described below, from the above calculation results, the applicant assumed a reason why the formation of the carbon-based film on the bottom of the trench can be prevented by lowering the maximum ion energy of the plasma. That is, when the maximum ion energy decreases and the angular distribution of ion energy becomes broader, the proportion of ions entering the wafer W at an angle increases. In doing so, the proportion of ions entering perpendicularly to the wafer W decreases compared to a case where the maximum ion energy is high. Further, given that there is a certain distance between a high-density plasma region 53 and the wafer W, ions that are not directed exactly perpendicular to the wafer W are less likely to reach the bottom of the trench. As a result, the formation of the carbon-based film 45 on the bottom of the trench is prevented.

Further, ions contributing to film formation on the side of the trench are those with an angle perpendicular to, or nearly perpendicular to, the wafer W. When the maximum ion energy of the plasma decreases and the angular distribution of ion energy becomes broader, such ions are reduced. In other words, lowering the maximum ion energy of the plasma also prevents the formation of the carbon-based film 45 on the side of the trench. It was also found that when the temperature of the wafer W is high at this time, the etching power of hydrogen radicals is enhanced and the carbon-based film 45 is formed only on the top of the fin 44a.

Furthermore, the applicant conducted film formation on the wafer W using film forming apparatuses having different configurations, in order to investigate an appropriate form for implementing the technique of the present disclosure. In addition, the film forming apparatuses used at this time have simplified configurations as illustrated in FIGS. 16A to 16C.

In each film forming apparatus, the applicant set the temperature of the wafer W to 400 degrees C. Further, the addition rate of the acetylene gas in the film-forming gas differs depending on the film forming apparatus but was adjusted to be at least 3% or more (with a flow rate of 30 sccm or more) in any film forming apparatus. Furthermore, the other components of the film-forming gas were the argon gas and hydrogen gas, with the flow rate of the argon gas set to 1,000 sccm.

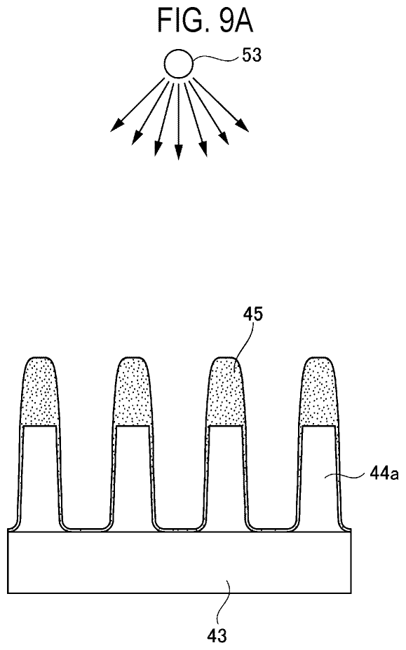

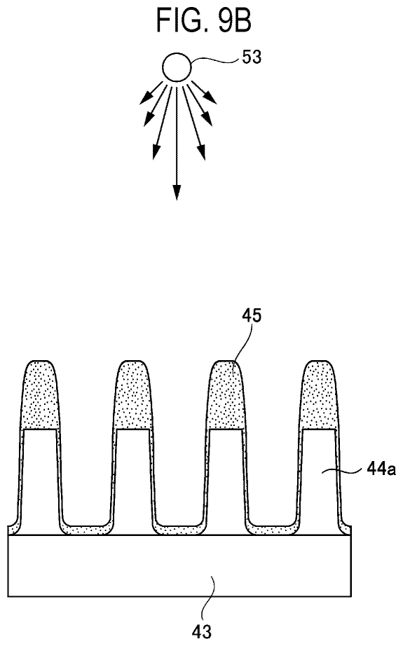

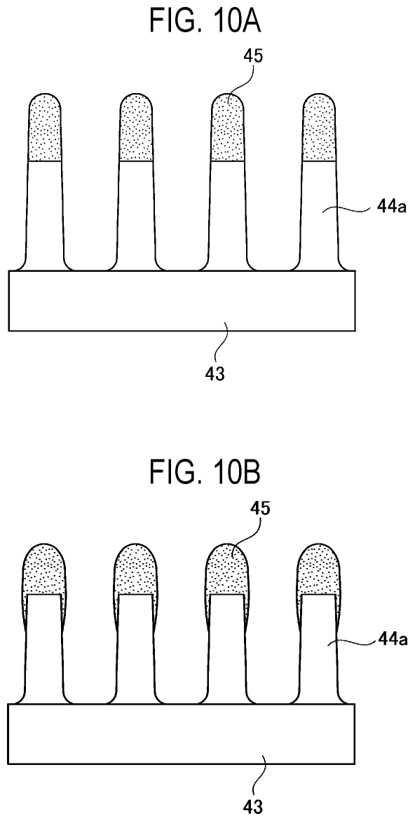

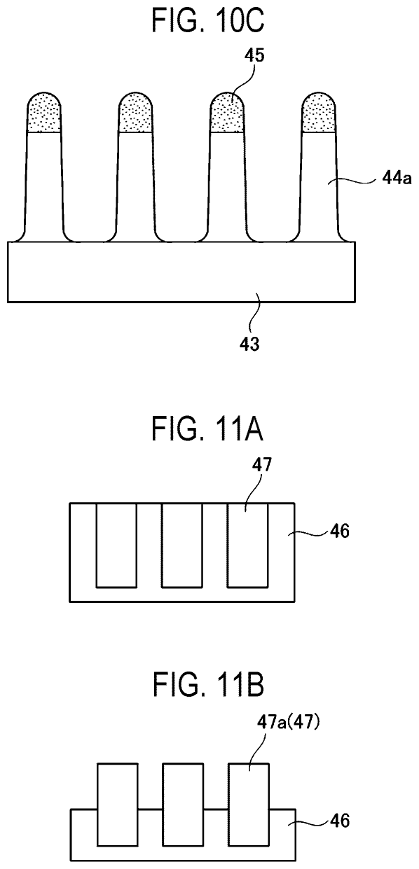

FIG. 10A is a diagram illustrating a film-forming pattern when film formation was performed on the wafer W using the film forming apparatus (evaluation apparatus) 40 illustrated in FIG. 16A. At this time, the internal pressure of the chamber 11 was set to 1 Torr, and radio frequency power with a frequency of 40 MHz was supplied at 500 W to the upper electrode 20 from the radio frequency power supply 32. FIG. 10B is a diagram illustrating a film-forming pattern when film formation was performed on the wafer W using a film forming apparatus 52 illustrated in FIG. 16B. At this time, the internal pressure of the chamber 11 was set to 100 mTorr, and radio frequency power with a frequency of 13.56 MHz was supplied at 1 kW to the upper electrode 20 from the radio frequency power supply 32. Further, an electrode plate 222 was connected to the ground, and a positive voltage of 100 V was applied to an electrode plate 221. FIG. 10C is a diagram illustrating a film-forming pattern when film formation was performed on the wafer W using a film forming apparatus 54 illustrated in FIG. 16C. At this time, the internal pressure of the chamber 11 was set to 1 Torr, and radio frequency power with a frequency of 450 kHz was supplied at 1 kW to the upper electrode 20 from the radio frequency power supply 32.

In addition, at this time, the applicant confirmed by an ion energy meter that the maximum ion energy of the plasma was 200 eV or lower during film formation in each film forming apparatus. Further, the applicant observed the film-forming patterns illustrated in FIGS. 10A, 10B, and 10C, and confirmed that regardless of the different configurations of the film forming apparatuses, the carbon-based film 45 was formed only on the top of the fin 44a, that the carbon-based film 45 did not overhang toward the trench, and that the carbon-based film 45 was hardly formed inside the trench. In addition, from a more detailed observation of the film-forming pattern of the carbon-based film 45 illustrated in FIG. 10B, it was confirmed that the carbon-based film 45 was formed thinly on the sidewall of the trench, but this film was very thin to the extent that it may be removed later by light ashing. In other words, it was confirmed that the carbon-based film 45, which is approximately appropriate for selective formation on the top of the fin 44a, was formed in the film forming apparatus 40, 52, and 54.

As described above, in the present embodiment, it was found that, in order to selectively form the appropriate carbon-based film 45 on the top of the fin 44a, it is necessary to set the temperature of the wafer W to at least 200 degrees C. or higher, and particularly 300 degrees C. or higher. Further, it was found that it is necessary to set the addition rate of the hydrogen gas to 3% or more in the film-forming gas consisting of the acetylene gas, argon gas, and hydrogen gas. Furthermore, it was found that it is necessary to set the aspect ratio of the trench in an underlying layer for the carbon-based film 45 to 2 or more, and particularly 4 or more. Further, it was found that it is more desirable to control the maximum ion energy of the plasma used for film formation to 200 eV or lower.

Further, according to the present embodiment, in the film forming apparatus 100, film formation is executed by setting the temperature of the wafer W to at least 200 degrees C. or higher and setting the addition rate of the hydrogen gas in the film-forming gas to 3% or more. This allows for the selective formation of the appropriate carbon-based film 45 on the top of the fin 44a of the oxide layer 44 in a single step. In other words, when selectively forming the carbon-based film 45 on the top of the trench, it is possible to prevent the occurrence of overhang of the carbon-based film 45 while improving throughput.

Next, an application example of a method of forming a carbon-based film according to the present embodiment will be described. As described above, since the method of forming a carbon-based film according to the present embodiment utilizes a variation in the adhesion probability of hydrocarbon radicals by temperature and a variation in the etching power of hydrogen radicals by temperature, an underlying layer for the carbon-based film does not affect the formation of the carbon-based film. Accordingly, the method of forming a carbon-based film according to the present embodiment may be applied not only to underlying layers composed of oxide insulating films or masks but also to underlying layers composed of metal wiring layers.

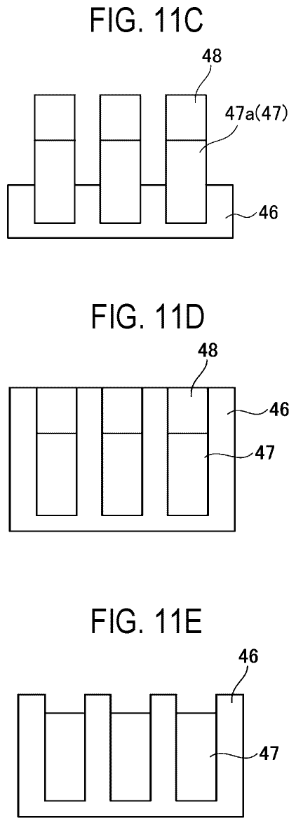

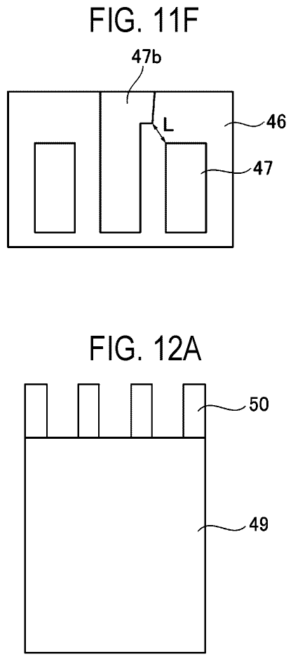

FIGS. 11A to 11F are process diagrams illustrating an example where a carbon-based film is selectively formed on the top of a metal protrusion, which serves as a wiring layer protruding from an interlayer insulating film. In FIGS. 11A to 11F, first, in the wafer W, a metal is buried into each trench of an interlayer insulating film 46 where a plurality of trenches are formed to form a wiring layer 47. At this time, an upper surface of the interlayer insulating film 46 and an upper surface of the wiring layer 47 are planarized by a method such as Chemical Mechanical Polishing (CMP) (FIG. 11A).

Subsequently, ashing is performed on the wafer W to selectively remove the interlayer insulating film 46, creating a recessed shape in the interlayer insulating film 46. At this time, the wiring layer 47 protrudes relative to the interlayer insulating film 46 and forms a metal protrusion 47a (FIG. 11B).

After that, in the film forming apparatus 100, the wafer W is accommodated in the interior of the chamber 11 and is placed on the stage 14, and the exhaust device 31 depressurizes the interior of the chamber 11. At this time, the heater 18 heats the stage 14 to set the temperature of the stage 14 to a temperature higher than 200 degrees C. Further, the gas supplier 28 supplies the film-forming gas consisting of the acetylene gas, argon gas, and hydrogen gas through the upper electrode 20. The addition rate of the hydrogen gas in the supplied film-forming gas is set to 3% or more. Further, the radio frequency power supply 32 supplies radio frequency power to the upper electrode 20. At this time, plasma is generated from the film-forming gas, and film formation is performed on the wafer W, selectively forming a carbon-based film 48 on the top of the metal protrusion 47a of the wiring layer 47 (FIG. 11C) (film formation).

Subsequently, film formation of an insulating film is performed on the wafer W to fill the recessed shape, by growing the interlayer insulating film 46. At this time, an upper surface of the interlayer insulating film 46 and an upper surface of the carbon-based film 48 are planarized by a method such as CMP (FIG. 11D).

After that, ashing is performed on the wafer W to completely remove the carbon-based film 48. At this time, an upper portion of the interlayer insulating film 46 is also removed simultaneously, but a recessed shape is created in the wiring layer 47 since the etching rate of the carbon-based film 48 is higher than the etching rate of the interlayer insulating film 46 (FIG. 11E).

Subsequently, a via hole 47b is formed through the reformation of the interlayer insulating film 46 or the partial addition of the wiring layer 47 (FIG. 11F). At this time, by reforming the interlayer insulating film 46, a sufficient separation distance L is ensured between the via hole 47b and the wiring layer 47 adjacent to that via hole 47b.

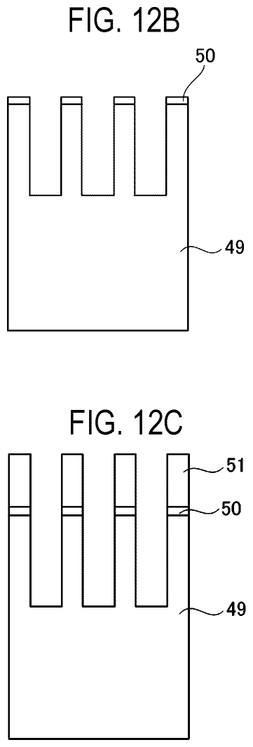

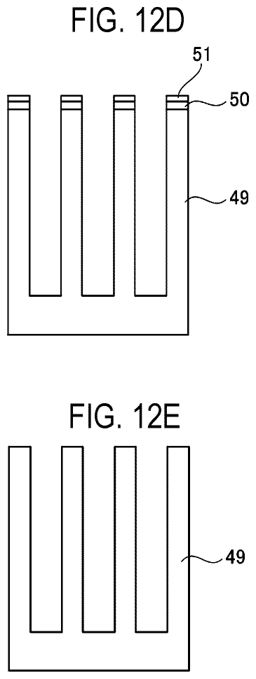

FIGS. 12A to 12E are process diagrams illustrating an example where a carbon-based film is selectively formed on the top of a trench in a hard mask. In FIGS. 12A to 12E, first, through the use of a hard mask 50 having a plurality of trenches, the wafer W is subjected to etching of an underlying oxide layer 49 under the hard mask 50 (FIG. 12A). As a result of the etching of the oxide layer 49, trenches corresponding to the trenches in the hard mask 50 are also formed in the oxide layer 49, but the hard mask 50 is also consumed (FIG. 12B).

Subsequently, in the film forming apparatus 100, film formation is performed on the wafer W under the same condition as in the example of FIGS. 11A to 11F. At this time, a carbon-based film 51 is selectively formed on the top of the trench of the consumed hard mask 50, extending the trench of the consumed hard mask 50 (FIG. 12C) (film formation). In addition, the aspect ratio of the trench in the oxide layer 49 during film formation is 2 or more.

Subsequently, the wafer W is subjected to the etching of the oxide layer 49. At this time, since the carbon-based film 51 functions as a mask, the trench in the oxide layer 49 extends corresponding to the trench in the carbon-based film 51. In addition, during the etching of the oxide layer 49, the carbon-based film 51 is mostly consumed, leaving only a very small amount of the carbon-based film 51 (FIG. 12D).

After that, ashing is performed on the wafer W to completely remove the remaining carbon-based film 51 or the consumed hard mask 50 (FIG. 12E). Thus, a trench with a high aspect ratio may be formed in the oxide layer 49.

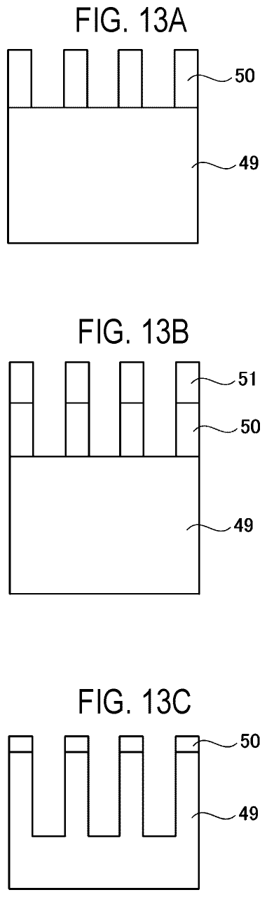

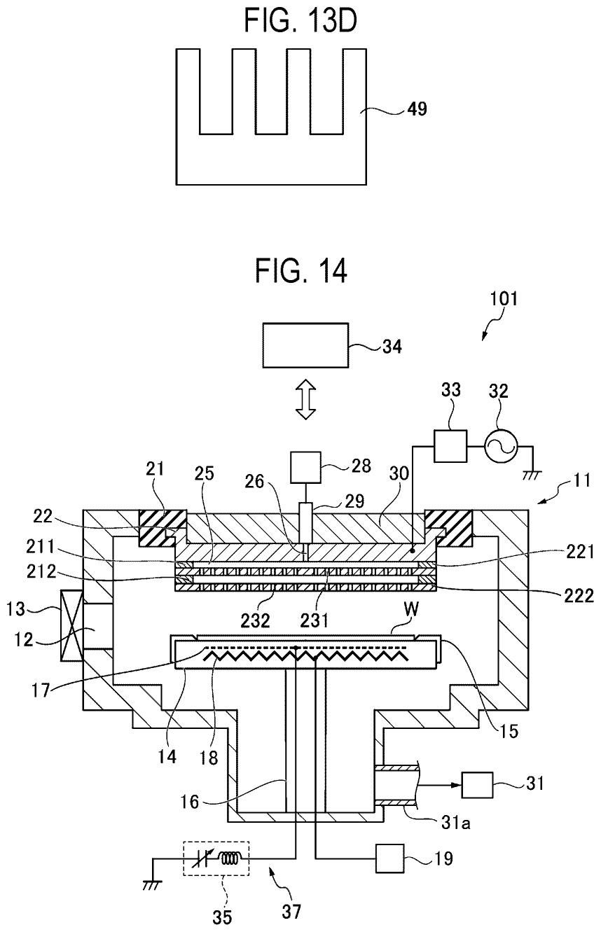

FIGS. 13A to 13D are process diagrams illustrating another example where the carbon-based film is selectively formed on the top of the trench in the hard mask. In FIGS. 13A to 13D, first, in the film forming apparatus 100, film formation is performed on the wafer W, on which the hard mask 50 having a plurality of trenches is formed, under the same condition as in the example of FIGS. 11A to 11F. At this time, the carbon-based film 51 is selectively formed on the top of the trench in the hard mask 50, extending the trench of the hard mask 50 (FIG. 13A) (film formation). In addition, the aspect ratio of the trench in the hard mask 50 during film formation is 2 or more.

Subsequently, through the use of the hard mask 50 having the trench extended by the carbon-based film 51, the wafer W is subjected to the etching of the oxide layer 49 under the mask 50 (FIG. 13B). As a result of the etching of the oxide layer 49, a trench with a high aspect ratio is formed in the oxide layer 49 to correspond to the extended trench in the hard mask 50, but the carbon-based film 51 is removed and the hard mask 50 is also consumed (FIG. 13C).

After that, ashing is performed on the wafer W to completely remove the consumed hard mask 50 (FIG. 13D).

While the preferred embodiments of the present disclosure have been described above, the present disclosure is not limited to the above-described embodiments, and various modifications and changes can be made within the scope of the spirit of the present disclosure.

For example, in the present embodiment, the carbon-based film was selectively formed on the top of the trench as a pattern, but it is also possible to selectively form the carbon-based film on the top of the hole as a pattern.

Further, in the present embodiment, the hydrocarbon gas (acetylene gas) was used as a hydrogen compound gas, in order to form the carbon-based film as a film to be selectively formed on the top of a pattern. However, other hydrogen compound gases may be used instead of the hydrocarbon gas. For example, a silane gas, which is a silicon hydrogen compound gas, or a borane gas, which is a boron hydrogen compound gas, may be used.

When film formation is performed on the wafer W using the film forming apparatus 100 with a film-forming gas consisting of a silane gas, argon gas, and hydrogen gas, a silicon-based film may be selectively formed on the top of a pattern without overhanging toward a trench or hole. Further, when film formation is performed on the wafer W using the film forming apparatus 100 with a film-forming gas consisting of a borane gas, argon gas, and hydrogen gas, a boron-based film may be selectively formed on the top of a pattern without overhanging toward a trench or hole.

Further, the film forming apparatus used to execute the method of forming a carbon-based film according to the present embodiment is not limited to the film forming apparatus 100 of FIG. 1.

FIG. 14 is a diagram illustrating a first modification of a film forming apparatus that executes the method of forming a carbon-based film according to the present embodiment. As illustrated in FIG. 14, a film forming apparatus 101 has a similar configuration to the film forming apparatus 100, with only the difference being that one or more electrode plates, such as two electrode plates 221 and 222, are arranged between the upper electrode 20 and the stage 14 instead of the ceiling plate 23 or the intermediate member 24.

In the film forming apparatus 101, an insulating member 211 is interposed between the base member 22 and the electrode plate 221, and an insulating member 212 is interposed between the electrode plate 221 and the electrode plate 222. This ensures that the base member 22, the electrode plate 221, and the electrode plate 222 are electrically independent of each other. In the film forming apparatus 101, the base member 22 functions as an upper electrode, and plasma is generated from the film-forming gas in the gas diffusion space 25.

Further, a number of through-holes 231 and 232 are provided in the electrode plates 221 and 222, respectively. Each through-hole 231 and each through-hole 232 are positioned to overlap each other when viewing the electrode plate 221 or the electrode plate 222 from the stage 14 side. Further, by controlling the potential of the electrode plates 221 and 222, ions, excluding radicals, from the plasma generated in the gas diffusion space 25 are accelerated. Since ions are highly anisotropic, they pass through the overlapped through-holes 231 and 232. In other words, the electrode plates 221 and 222 function as a kind of filter that selectively allows highly anisotropic ions to pass through and reach the wafer W.

Further, by controlling the potential of the electrode plates 221 and 222, the energy of the passing ions may be reduced, thereby reducing the ion energy imparted to the wafer W. At this time, for example, the electrode plate 222 is connected to the ground, and a negative voltage of −100 V is applied to the electrode plate 221. In addition, in the film forming apparatus 101, the radio frequency power supply 32 supplies radio frequency power within a frequency ranging from 200 kHz to 460 MHz to the upper electrode 20.

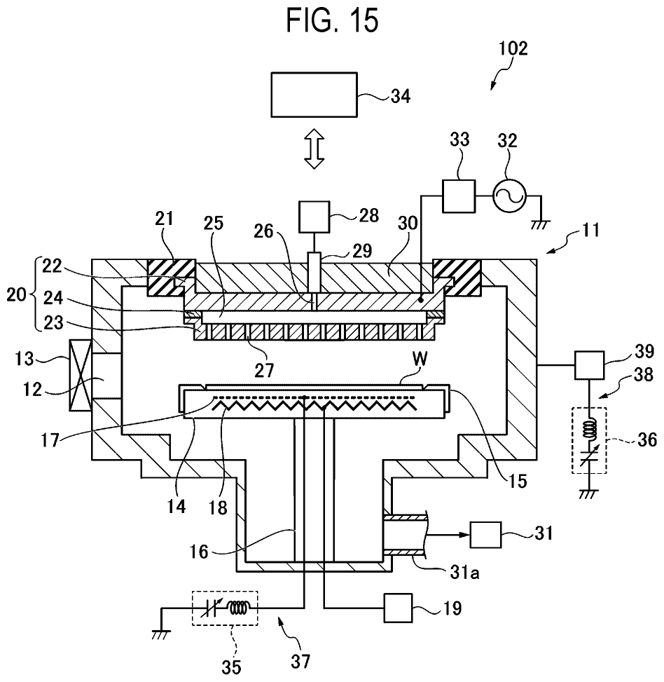

FIG. 15 is a diagram illustrating a second modification of a film forming apparatus that executes the method of forming a carbon-based film according to the present embodiment. As illustrated in FIG. 15, a film forming apparatus 102 has a similar configuration to the film forming apparatus 100, with the only difference being that it further includes a second impedance circuit 36 (impedance adjuster).

The second impedance circuit 36 is positioned in a second electrical path 38 that connects the wall of the chamber 11 to the ground. In addition, a current sensor 39 is also positioned in the second electrical path 38 to measure the value of a current flowing through the second electrical path 38. The second impedance circuit 36 includes a series circuit of a variable inductor and a variable capacitor, allowing the impedance between the wall of the chamber 11 and the ground to be changed.

In the film forming apparatus 102, the impedance of the first electrical path 37 is set to be higher than the impedance of the second electrical path 38 by the first impedance circuit 35 or the second impedance circuit 36 controlled by the controller 34. This may weaken the electrical coupling between the upper electrode 20 and the lower electrode 17, reducing the current flowing to the lower electrode 17 and consequently, reducing the plasma ion energy near the lower electrode 17. As a result, the ion energy imparted to the wafer W placed on the stage 14 is reduced.

Further, the method of forming a carbon-based film according to the present embodiment may also be executed using the film forming apparatus 40 illustrated in FIG. 16A.

Further, the method of forming the carbon-based film according to the present embodiment may also be executed using the simplified film forming apparatus 52 as illustrated in FIG. 16B. In addition, the film forming apparatus 52 is a capacitively coupled plasma processing apparatus. Similar to the film forming apparatus 101, the film forming apparatus 52 includes two electrode plates 221 and 222 arranged between the upper electrode 20 and the stage 14. Further, similar to the film forming apparatus 101, the potential of the electrode plates 221 and 222 may be controlled to select ions from the generated plasma.

Further, when controlling the potential of the electrode plates 221 and 222, for example, the electrode plate 222 is connected to the ground and a positive voltage is applied to the electrode plate 221, in order to stabilize plasma generation. At this time, positive ions in the plasma are accelerated by the potential difference between the electrode plate 221, to which the positive voltage is applied, and the electrode plate 222 connected to the ground. In other words, the positive ions in the plasma are adjusted to an appropriate ion energy by changing the voltage value of the positive voltage applied to the electrode plate 221 and are then supplied to the wafer W.

In addition, in the film forming apparatus 101, it is possible to execute the method of forming a carbon-based film according to the present embodiment as long as there is at least one electrode plate arranged between the stage 14 and the upper electrode 20. If there is only one electrode plate, it is desirable that the frequency of radio frequency power supplied to the upper electrode 20 be 40 MHz or higher in order to reduce the plasma potential. If there are two or more electrode plates, the potential difference in a region where positive ions in the plasma pass through may be finely adjusted, improving the controllability of ion energy. Therefore, the frequency of radio frequency power applied to the upper electrode 20 may be set over a wide range, for example, from 200 kHz to 460 MHz.

As described above, even when using the film forming apparatus 52, it is possible to reduce the ion energy imparted to the wafer W placed on the stage 14, similar to the film forming apparatus 100. In other words, film formation executed in the film forming apparatus 100 may be replicated in the film forming apparatus 52.

Further, the method of forming a carbon-based film according to the present embodiment may also be executed using the simplified film forming apparatus 54 as illustrated in FIG. 16C. In addition, the film forming apparatus 54 is a typical capacitively coupled plasma processing apparatus. In the film forming apparatus 52, a conductive ring member 41 is arranged to surround the stage 14 (lower electrode 17) in the interior of the chamber 11, with the ring member 41 being directly grounded while the lower electrode 17 is grounded through the first impedance circuit 35. The first impedance circuit 35 imparts a high impedance to the first electrical path 37. Accordingly, the impedance of the first electrical path 37 becomes higher than the impedance of a third electrical path 42 that connects the ring member 41 to the ground, reducing the ion energy imparted to the wafer W placed on the stage 14, similar to the film forming apparatus 100. In other words, the evaluation apparatus 40 may replicate film formation executed in the film forming apparatus 100. In addition, the evaluation apparatus 40 does not have the second impedance circuit 36 or the second electrical path 38.

According to the technique of the present disclosure, it is possible to improve throughput while preventing the occurrence of overhang of a carbon-based film when selectively forming the carbon-based film on the top of a pattern such as a trench or hole.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A method of forming a carbon-based film, comprising forming the carbon-based film on a substrate having a pattern,
wherein, in the forming the carbon-based film, plasma is generated from a film-forming gas consisting of a hydrocarbon gas, argon gas, and hydrogen gas to selectively form the carbon-based film on a top of the pattern.

2. The method of claim 1, wherein the hydrocarbon gas is an acetylene gas.

3. The method of claim 1, wherein in the forming the carbon-based film, a temperature of the substrate is set to be higher than 200 degrees C.

4. The method of claim 3, wherein in the forming the carbon-based film, the temperature of the substrate is set to be 300 degrees C. or higher.

5. The method of claim 1, wherein an addition rate of the hydrogen gas in the film-forming gas is 3% or more.

6. The method of claim 1, wherein the pattern is either a trench or a hole.

7. The method of claim 6, wherein an aspect ratio of the trench and the hole is 2 or more.

8. The method of claim 7, wherein the aspect ratio of the trench and the hole is 4 or more.

9. The method of claim 1, wherein in the forming the carbon-based film, the substrate is accommodated in a processing chamber with a depressurized interior and is placed on a stage arranged in the interior of the processing chamber, the plasma is generated from the film-forming gas in the interior of the processing chamber, and a maximum ion energy of the plasma is controlled to 200 eV or lower.

10. The method of claim 1, wherein in the forming the carbon-based film, the substrate is accommodated in a processing chamber with a depressurized interior and is placed on a stage arranged in the interior of the processing chamber, the plasma is generated from the film-forming gas in the interior of the processing chamber, and a frequency of 40 MHz or higher is applied to an electrode facing the stage.

11. The method of claim 1, wherein in the forming the carbon-based film, the substrate is accommodated in a processing chamber with a depressurized interior and is placed on a stage arranged in the interior of the processing chamber, and the plasma is generated from the film-forming gas in the interior of the processing chamber, and
wherein at least one electrode is arranged between the stage and an electrode facing the stage.

12. The method of claim 1, wherein in the forming the carbon-based film, the substrate is accommodated in a processing chamber with a depressurized interior and is placed on a stage arranged in the interior of the processing chamber, the plasma is generated from the film-forming gas in the interior of the processing chamber, and an impedance between the stage and a ground is set higher than an impedance between a wall of the processing chamber and the ground.

13. The method of claim 1, wherein the pattern is a metal protrusion protruding from an interlayer insulating film, and the carbon-based film is selectively formed on a top of the metal protrusion.

14. The method of claim 1, wherein the pattern is a trench or a hole formed in a hard mask, and the carbon-based film is selectively formed on a top of the trench or the hole.

15. The method of claim 14, wherein after etching a layer under the hard mask using the hard mask, the carbon-based film is selectively formed on the top of the trench or the hole in the hard mask consumed by the etching.

16. The method of claim 14, wherein the carbon-based film is selectively formed on the top of the trench or the hole in the hard mask before etching a layer under the hard mask using the hard mask.

17. A film forming apparatus comprising a processing chamber with a depressurized interior,
wherein a substrate having a pattern is accommodated in an interior of the processing chamber, and plasma is generated from a film-forming gas consisting of a hydrocarbon gas, argon gas, and hydrogen gas in the interior of the processing chamber to selectively form a carbon-based film on a top of the pattern.

18. The film forming apparatus of claim 17, wherein a maximum ion energy of the plasma generated in the interior of the processing chamber is controlled to 200 eV or lower.

19. The film forming apparatus of claim 17, further comprising:
a stage configured to place the substrate thereon;
an electrode facing the stage; and
a radio frequency power supply configured to supply radio frequency power with a frequency of 40 MHz or higher to the electrode.

20. The film forming apparatus of claim 17, further comprising:
a stage configured to place the substrate thereon;
an electrode facing the stage; and
at least one electrode arranged between the stage and the electrode.

21. The film forming apparatus of claim 17, further comprising:
a stage configured to place the substrate thereon; and
an impedance adjuster configured to set an impedance between the stage and a ground to be higher than an impedance between a wall of the processing chamber and the ground.
